(19) United States
(12) Patent Application Publication
(10) Pub. No.: US 2023/0019554 A1
(43) Pub. Date: Jan. 19, 2023

(54) METHOD FOR MANUFACTURING PRINTED WIRING BOARD AND COATING SYSTEM FOR IMPLEMENTING THE METHOD

(71) Applicant: IBIDEN CO., LTD., Ogaki (JP)

(72) Inventors: Yuji KADOWAKI, Ogaki (JP); Tomomi KANO, Ogaki (JP)

(73) Assignee: IBIDEN CO., LTD., Ogaki (JP)

(21) Appl. No.: 17/811,707

(22) Filed: Jul. 11, 2022

(30) Foreign Application Priority Data
Jul. 14, 2021 (JP) 2021-116319

(51) Int. Cl. H05K 3/02; H05K 3/00; C25D 5/02; C25D 5/22; C25D 5/54; C25D 7/00

(52) U.S. Cl. CPC H05K 3/02; H05K 3/0011; C25D 5/022; C25D 5/22; C25D 5/54; C25D 7/00

(57) ABSTRACT

A method for manufacturing a printed wiring board includes forming a seed layer on a surface of a resin insulating layer, applying liquid resist on the seed layer formed on the surface of the resin insulating layer, drying the liquid resist applied on the seed layer such that a resist layer is formed on the seed layer, applying pressure and heat simultaneously to an entire surface of the resist layer formed on the seed layer, forming a plating resist on the seed layer from the resist layer formed on the seed layer using a photographic technology, forming an electrolytic plating film on part of the seed layer exposed from the plating resist, removing the plating resist from the seed layer, and removing part of the seed layer exposed from the electrolytic plating film.

### CROSS-REFERENCE TO RELATED APPLICATIONS

The present application is based upon and claims the benefit of priority to Japanese Patent Application No. 2021-116319, filed Jul. 14, 2021, the entire contents of which are incorporated herein by reference.

### BACKGROUND OF THE INVENTION

### Field of the Invention

The present invention relates to a method for manufacturing a printed wiring board in which a liquid resist is applied on a seed layer formed on a resin insulating layer, and relates to a coating system used in implementing the method.

### Description of Background Art

Japanese Patent Application Laid-Open Publication No. H05-068922 describes a coating device that applies a liquid resist on a surface of a printed wiring board. The entire contents of this publication are incorporated herein by reference.

### SUMMARY OF THE INVENTION

According to one aspect of the present invention, a method for manufacturing a printed wiring board includes forming a seed layer on a surface of a resin insulating layer, applying liquid resist on the seed layer formed on the surface of the resin insulating layer, drying the liquid resist applied on the seed layer such that a resist layer is formed on the seed layer, applying pressure and heat simultaneously to an entire surface of the resist layer formed on the seed layer, forming a plating resist on the seed layer from the resist layer formed on the seed layer using a photographic technology, forming an electrolytic plating film on part of the seed layer exposed from the plating resist, removing the plating resist from the seed layer, and removing part of the seed layer exposed from the electrolytic plating film.

According to another aspect of the present invention, a coating system includes a liquid resist coating device that applies a liquid resist on a seed layer formed on a resin insulating layer, a liquid resist drying device that dries the liquid resist applied on the seed layer formed on the resin insulating layer and form a resist layer on the seed layer, and a pressure and heat application device that applies pressure and heat to an entire surface of the resist layer.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a conceptual diagram illustrating a structure of a coating system according to an embodiment of the present invention;

FIG. 2 is a cross-sectional view for describing a coating system according to an embodiment of the present invention;

FIG. 3 is a side view for describing a coating system according to another embodiment of the present invention;

FIG. 4A is a cross-sectional view describing a state in which a void exists between a seed layer and a resist layer; and

FIG. 4B is a cross-sectional view describing a state in which no void exists between the seed layer and the resist layer.

### DETAILED DESCRIPTION OF THE EMBODIMENTS

Embodiments will now be described with reference to the accompanying drawings, wherein like reference numerals designate corresponding or identical elements throughout the various drawings.

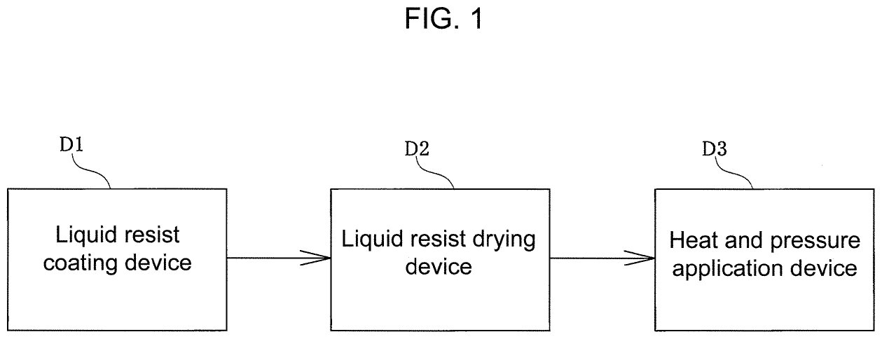

As illustrated in a conceptual diagram of FIG. 1, a coating system according to an embodiment of the present invention includes a liquid resist coating device (D1) that applies a liquid resist on a seed layer formed on a resin insulating layer, a liquid resist drying device (D2) that dries the liquid resist applied on the seed layer formed on the resin insulating layer to form a resist layer, and a heat and pressure application device (D3) that applies heat and pressure to an entire surface of the resist layer.

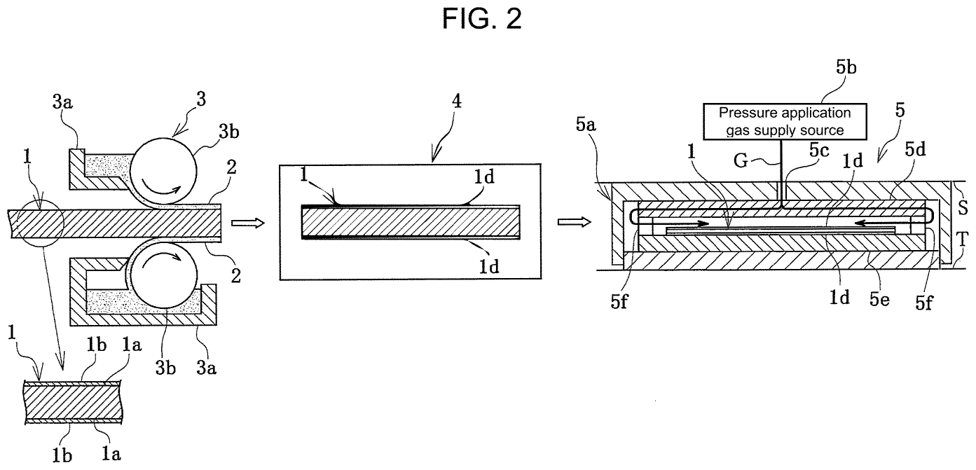

And as illustrated in FIG. 2, a method for manufacturing a printed wiring board according to an embodiment of the present invention includes preparing a resin insulating layer (1a), forming a seed layer (1b) on a surface of the resin insulating layer (1a), applying a liquid resist 2 on the seed layer (1b) using a roll coater 3 as an example of the liquid resist coating device (D1), forming a resist layer (1d) by drying the liquid resist 2 applied on the seed layer (1b) using a heat drying device 4 as an example of the liquid resist drying device (D2), applying heat and pressure to the resist layer (1d) formed on the seed layer (1b) with a heat and pressure application device 5 as an example of the heat and pressure application device (D3), forming a plating resist from the resist layer (1d) using a photographic technology, forming an electrolytic plating film on the seed layer (1b) exposed from the plating resist; removing the plating resist, and removing the seed layer (1b) exposed from the electrolytic plating film.

In the method for manufacturing the printed wiring board of the embodiment, applying heat and pressure to the resist layer (1d) is conducted after forming the resist layer (1d) on the seed layer (1b). In the method for manufacturing the printed wiring board of the embodiment, applying heat and pressure to the resist layer (1d) is conducted before forming the plating resist from the resist layer (1d). And, in the method for manufacturing the printed wiring board of the embodiment, applying heat and pressure to the resist layer (1d) formed on the seed layer (1b) is simultaneously conducted with respect to an entire surface of the resist layer (1d).

FIG. 2 is a cross-sectional view for describing a coating system according to an embodiment of the present invention for implementing a method for manufacturing a printed wiring board according to an embodiment of the present invention. The reference numeral symbol “1” in FIG. 2 indicates, for example, a build-up type printed wiring board in which insulating layers and conductor layers are alternately laminated on both sides of a core substrate. As illustrated by enlarging a part of the printed wiring board 1, resin insulating layers (1a) each forming an insulating layer that covers a lower-layer conductor layer are respectively provided on both sides of the printed wiring board 1.

As the resin insulating layers (1a), for example, insulating resin films can be used, and, in particular, in order to meet a demand for reduction in transmission loss of high-frequency signals in recent years, it is desirable to use insulating resin films having a low surface roughness.

On surfaces of the resin insulating layers (1a) on both sides of the printed wiring board 1, seed layers (1b) are respectively formed, which later become power feeding layers when the conductor layers are formed by electrolytic copper plating. In the method for manufacturing the printed wiring board of this embodiment, before forming the seed layers (1b) on the surfaces of the resin insulating layers (1a), the surfaces of the resin insulating layers (1a) are roughened, and an arithmetic mean roughness (Ra) of the surfaces of the seed layers (1b) formed on the resin insulating layers (1a) is 0.3 μm or less. The seed layers (1b) are formed, for example, by electroless copper plating.

Next, in the method for manufacturing the printed wiring board of this embodiment, the coating system of the embodiment illustrated in FIG. 2 is used to respectively coat, for example, photosensitive resist layers (1d), which later serve as plating resists when the conductor layers are formed by electrolytic plating, on the seed layers (1b) formed on the surfaces of the resin insulating layers (1a).

The coating system of this embodiment includes: as an example of the liquid resist coating device (D1), the roll coater 3 that applies photosensitive liquid resists 2 at a predetermined thickness on the seed layers (1b) formed on the surfaces of the resin insulating layers (1a) on both sides of the sheet-like printed wiring board 1 formed or cut into a predetermined shape such as a rectangular shape; and, as an example of the liquid resist drying device (D2), a heat drying device 4 that forms the resist layers (1d) by applying heat to the printed wiring board 1 to dry the liquid resists 2 applied on the seed layers (1b) and removing a predetermined amount of a solvent from the liquid resists 2.

Here, the roll coater 3 includes a pair of doctor bars (3a) positioned above and below the printed wiring board 1, which is carried from left to right in the drawing by a carrying device (not illustrated in the drawing), and a pair of coating rolls (3b) positioned above and below the printed wiring board 1 so as to be adjacent to the doctor bars (3a). Each of the doctor bars (3a) is provided with a storage tank, and the liquid resists 2 stored in the storage tanks are supplied to surfaces of the coating rolls (3b) at a predetermined constant thickness. The supply thickness of the liquid resists 2 can be set to a desired thickness by adjusting a distance from the liquid resists 2 to the surfaces of the coating rolls (3b), and temperature and hardness of the liquid resists 2.

Each of the coating rolls (3b) is formed, for example, by lining a heat resistant silicone rubber on an outer peripheral portion of a metal cylindrical roll to a thickness of 1 mm-4 mm, and are rotationally driven in opposite directions as indicated by the arrows by a drive mechanism (not illustrated in the drawings). The liquid resists 2, which are supplied at a constant thickness by the doctor bars (3a) to surfaces of the silicone rubbers lined on the outer peripheral portions of the cylindrical rolls, are pressed onto the seed layers (1b) formed on the surfaces of the resin insulating layers (1a) of the printed wiring board 1, which is carried from left to right as described above, and are applied at a predetermined constant thickness that is substantially equal to the supply thickness from the doctor bars (3a).

For example, the heat drying device 4 includes: a drying chamber that accommodates the printed wiring board 1 in which the liquid resists 2 have been applied on the seed layers (1b) by the coating rolls (3b); and an electric heater that heats the printed wiring board 1 in the drying chamber. The heat drying device 4 forms the resist layers (1d) on the seed layers (1b) by removing a predetermined amount of the solvent from the liquid resists 2 by drying the liquid resists 2 by applying heat to the printed wiring board 1 accommodated in the drying chamber at a predetermined temperature for a predetermined time.

The coating system of this embodiment further includes, as an example of the heat and pressure application device (D3), the heat and pressure application device 5 that applies a pressure to the printed wiring board 1 in which the resist layers (1d) have been formed on the seed layers (1b) in a state that the printed wiring board 1 has been heated.

Here, the pressure and heat application device 5 includes: a pressure application container (5a) that is openable and closeable and accommodates in an airtight state the printed wiring board 1 in which the resist layers (1d) have been formed on the seed layers (1b); a pressure application gas (G) as a pressure source injected into the pressure application container (5a) from a pressure application gas supply source (5b) via a pressure application gas inlet (5c); an upper hot plate (5d) and a lower hot plate (5e), which together with the pressure application gas (G) heated by the upper hot plate (5d) and the lower hot plate (5e) serve as a heat source that applies heat to the printed wiring board 1 in which the resist layers (1d) have been formed in the pressure application container (5a); and a spacer (5f) that is inserted between a peripheral edge part of the upper hot plate (5d) and a peripheral edge part of the lower hot plate (5e) and forms a space in an up-down direction between the upper hot plate (5d) and the lower hot plate (5e).

Each of the upper hot plate (5d) and the lower hot plate (5e) has, for example, a built-in electric heater (not illustrated in the drawings). The pressure application gas (G) is supplied via the compressed air inlet (5c) of the pressure application container (5a) to the space between the upper hot plate (5d) and the lower hot plate (5e) as indicated by the arrows in the drawing. The pressure application gas (G) is, for example, compressed air. The pressure application gas supply source (5b) is, for example, a compressed air supply line, an air compressor, or the like.

In a coating method of this embodiment using the coating system of the above embodiment, first, the liquid resists 2 are applied by pressing by the pair of coating rolls (3b) of the roll coater 3 onto the seed layers (1b) formed on the surfaces of the resin insulating layers (1a). Most of air sandwiched between the seed layers (1b) and the liquid resists 2 during the application of the liquid resists 2 is removed from between the seed layers (1b) and the liquid resists 2 by the pressing without forming voids.

Next, the printed wiring board 1 in which the liquid resists 2 have been applied on the seed layers (1b) on the surfaces of the resin insulating layers (1a) is accommodated in the drying chamber of the heat drying device 4 and is heated by the electric heater at a predetermined temperature for a predetermined time to dry the liquid resists 2, and thereby, a predetermined amount of the solvent is removed from the liquid resists 2, and the resist layers (1d) are formed on the seed layers (1b) on the surfaces of the resin insulating layers (1a).

Next, between the upper hot plate (5d) and the lower hot plate (5e) positioned in the pressure application container (5a) of the heat and pressure application device 5, the printed wiring board 1 (in which the resist layers (1d) have been formed) as an intermediate substrate during a manufacturing process of a printed wiring board as a product is positioned in a state of having a surrounding space formed by the spacer (5f). Then, the pressure application container (5a) is held, for example, on a table (T) of a normal pressing device by a slide (S) of the pressing device so as not to be opened by the pressure of the pressure application gas (G), and the printed wiring board 1 in which the resist layers (1d) have been formed is accommodated in the pressure application container (5a) in an airtight state.

Next, with respect to the entire resist layers (1d), in the state in which the surrounding space is formed, a pressure is simultaneously applied by the pressure application gas (G) supplied from the pressure application gas inlet (5c) connected to the pressure application gas supply source (5b), and heat is simultaneously applied by the upper hot plate (5d) and the lower hot plate (5e) and the pressure application gas (G) heated by the upper hot plate (5d) and the lower hot plate (5e).

Applying heat and pressure to the resist layers (1d) is conducted after forming the resist layers (1d) on the seed layers (1b). Further, applying heat and pressure to the resist layers (1d) is conducted before forming plating resists to be described later. Due to the pressure application and the heat application, air bubbles trapped between the seed layers (1b) on the surfaces of the resin insulating layers (1a) and the liquid resists 2 when the liquid resists 2 are applied on the seed layers (1b) with the coating rolls (3a) as described above are thought to dissolve in the liquid resists 2.

Next, the plating resists are formed from the resist layers (1d) using a photographic technology. The plating resists have openings corresponding to conductor circuits formed in the printed wiring board 1. Next, electrolytic copper plating films are respectively formed on the seed layers (1b) exposed from the openings of the plating resists. After that, the plating resists are removed, and the seed layers (1b) that are exposed without being covered by the electrolytic copper plating films are removed. As a result, conductor circuits formed of the seed layers (1b) and the electrolytic copper plating films are formed on the surfaces of the resin insulating layers (1a) on both sides of the printed wiring board 1.

### Example

In a method according to an example of the present invention, in the pressure application container (5a), a temperature of a surrounding atmosphere of the printed wiring board 1, in which the resist layers (1d) have been formed on the seed layers (1b) having a low surface roughness, was raised to 45° C. or higher and 75° C. or lower by the upper hot plate (5d) and the lower hot plate (5e), and a pressure of the surrounding atmosphere was increased to 0.2 MPa or more and 0.6 MPa or less by the pressure application gas (G) from the pressure application gas inlet (5c), and a pressure application time was set to 20 seconds-30 seconds. According to the method of this example, voids due to air bubbles trapped between the seed layers (1b) on the surfaces of the resin insulating layers (1a) and the liquid resists 2 when the liquid resists 2 are applied onto the seed layers (1b) with the coating rolls (3b) disappeared after the heat and pressure application by the heat and pressure application device 5.

### Comparative Example

On the other hand, in a method of a comparative example, in the pressure application container (5a), the temperature of the surrounding atmosphere of the printed wiring board 1, in which the resist layers (1d) have been formed on the seed layers (1b) having a low surface roughness, was raised to the room temperature or higher and 40° C. or lower by the upper hot plate (5d) and the lower hot plate (5e), and the pressure of the surrounding atmosphere was increased to 0.2 MPa or more and 0.6 MPa or less by the pressure application gas (G) from the pressure application gas inlet (5c), and a pressure application time was set to 20 seconds-3 minutes. According to the method of this comparative example, voids due to air bubbles trapped between the seed layers (1b) on the surfaces of the resin insulating layers (1a) and the liquid resists 2 when the liquid resists 2 are applied onto the seed layers (1b) with the coating rolls (3b) remained even after the heat and pressure application by the heat and pressure application device 5.

It is thought that the difference between the disappearance of the voids in the example and the remaining of the voids in the comparative example is due to that, according to Henry's law that, with respect to a gas component (B) under a constant temperature, the relation PB=K*xB holds where PB is a pressure, xB is an amount of a dissolved substance, and K is a temperature-dependent constant (Henry constant), since an amount of a substance of a gas (air) that dissolves in a solvent (the resist layers (1d) softened due to heat application) is proportional to a pressure with respect to a certain amount of the solvent under a constant temperature, dissolution and disappearance of the voids progresses when a pressure is applied.

Therefore, according to the method of this embodiment, air bubbles trapped between the seed layers (1b) on the surfaces of the resin insulating layers (1a) and the liquid resists 2 when the liquid resists 2 are applied onto the seed layers (1b) on the surfaces of the resin insulating layers (1a) with the coating rolls (3b) can be effectively prevented from forming voids later.

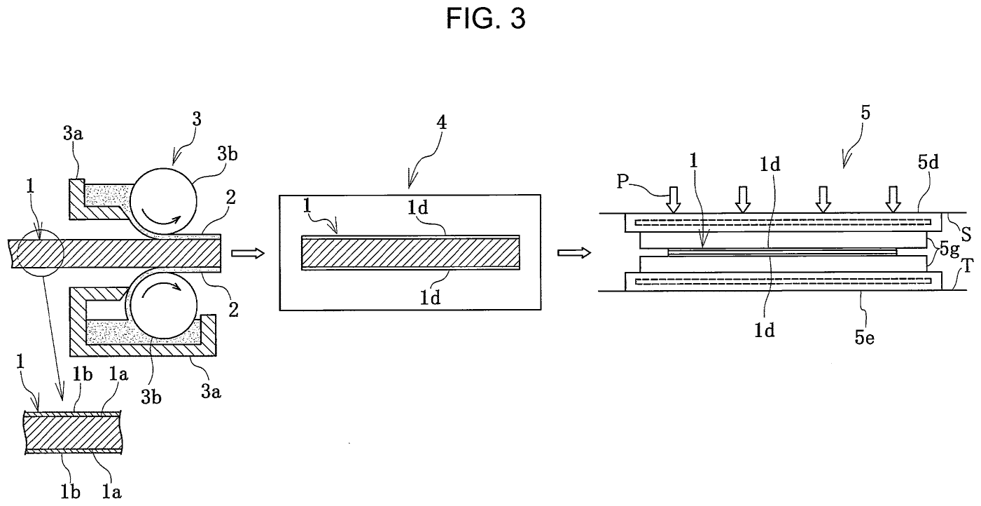

FIG. 3 is a side view for describing a coating system according to another embodiment of the present invention for implementing a method for manufacturing a printed wiring board according to an embodiment of the present invention, and a portion that is the same as in FIG. 2 is indicated using the same reference numeral symbol.

That is, the reference numeral symbol “1” indicates, for example, a build-up type printed wiring board in which insulating layers and conductor layers are alternately laminated on both sides of a core substrate. As illustrated by enlarging a part of the printed wiring board 1, resin insulating layers (1a) each forming an insulating layer that covers a lower-layer conductor layer are respectively provided on both sides of the printed wiring board 1. On surfaces of these resin insulating layers (1a), seed layers (1b) are respectively formed, which later serve as power feeding layers when the conductor layers are formed by electrolytic copper plating.

As the resin insulating layers (1a), for example, insulating resin films can be used, and, in particular, in order to meet a demand for reduction in transmission loss of high-frequency signals in recent years, it is desirable to use insulating resin films having a low surface roughness.

In the method for manufacturing the printed wiring board of this embodiment, the coating system of the embodiment illustrated in FIG. 3 is used to respectively coat, for example, photosensitive liquid resists 2, which later serve as plating resists when conductor layers are formed by electrolytic plating, on the seed layers (1b) formed on the surfaces of the resin insulating layers (1a).

Similar to the coating system of the embodiment described above, the coating system of this embodiment includes: as an example of the liquid resist coating device (D1), the roll coater 3 that applies the photosensitive liquid resists 2 at a predetermined thickness on the seed layers (1b) formed on the surfaces of the resin insulating layers (1a) of the sheet-like printed wiring board 1 formed or cut into a predetermined shape such as a rectangular shape; and, as an example of the liquid resist drying device (D2), the heat drying device 4 that forms the resist layers (1d) by applying heat to the printed wiring board 1 to dry the liquid resists 2 applied on the seed layers (1b) and removing a predetermined amount of a solvent from the liquid resists 2.

The coating system of this embodiment further includes, as an example of the heat and pressure application device (D3), a heat and pressure application device 5 that applies a pressure to the printed wiring board 1 in which the resist layers (1d) have been formed on the seed layers (1b) in a state that the printed wiring board 1 has been heated.

Here, the heat and pressure application device 5 includes: two flat pressing plates (5g) as a pressure source sandwiching from above and below the printed wiring board 1 in which the resist layers (1d) have been formed on the seed layers (1b); and an upper hot plate (5d) and a lower hot plate (5e) as a heat source heating, via the pressing plates (5g), the printed wiring board 1 in which the resist layers (1d) have been formed. The two flat pressing plates (5g) are formed of, for example, stainless steel. Further, each of the upper hot plate (5d) and the lower hot plate (5e) is, for example, a built-in electric heater (not illustrated in the drawings).

In a coating method of this embodiment using the coating system of the above embodiment, first, the liquid resists 2 are applied by pressing by the pair of coating rolls (3b) of the roll coater 3 onto the seed layers (1b) formed on the surfaces of the resin insulating layers (1a). Most of air sandwiched between the seed layers (1b) and the liquid resists 2 during the application of the liquid resists 2 is removed from between the seed layers (1b) and the liquid resists 2 by the pressing without forming voids.

Next, the printed wiring board 1 in which the liquid resists 2 have been applied on the seed layers (1b) on the surfaces of the resin insulating layers (1a) is accommodated in the drying chamber of the heat drying device 4 and is heated by the electric heater at a predetermined temperature for a predetermined time to dry the liquid resists 2, and thereby, a predetermined amount of the solvent is removed from the liquid resists 2, and the resist layers (1d) are formed on the seed layers (1b) on the surfaces of the resin insulating layers (1a).

Next, one of the two pressing plates (5g) of the heat and pressure application device 5 is mounted, for example, on a table (T) of a pressing device via the lower hot plate (5e) of the heat and pressure application device 5, and the other one of the two pressing plate (5g) of the heat and pressure application device 5 is mounted on a slide (S) of the pressing device via the upper hot plate (5d) of the heat and pressure application device 5. The printed wiring board 1 in which the resist layers (1d) have been formed is positioned between those pressing plates (5g). The upper hot plate (5d) is pressed toward the lower hot plate (4e) with the slide (S) of the pressing device with a pressing force as indicated by arrows (P) in the drawing. A pressure is simultaneously applied by the two pressing plates (5g) to the entire resist layers (1d) formed on the two sides of the printed wiring board 1, and heat is simultaneously applied by the upper hot plate (5d) and the lower hot plate (5e) via the two pressing plates (5g).

Applying heat and pressure to the resist layers (1d) is conducted after forming the resist layers (1d) on the seed layers (1b). Further, applying heat and pressure to the resist layers (1d) is conducted before forming plating resists to be described later.

After that, similar to the method of the embodiment described above, the plating resists are formed from the resist layers (1d) formed on the seed layers (1b) by exposure and development, which are photographic technologies. The plating resists have openings corresponding to conductor circuits formed in the printed wiring board 1. Next, electrolytic copper plating films are respectively formed on the seed layers (1b) exposed from the openings of the plating resists. After that, the plating resists are removed, and the seed layers (1b) that are exposed without being covered by the electrolytic copper plating films are removed. As a result, conductor circuits formed of the seed layers (1b) and the electrolytic copper plating films are formed on the surfaces of the resin insulating layers (1a) on both sides of the printed wiring board 1.

Also, according to the method of this embodiment, by the heat and pressure application by the heat and pressure application device 5, air bubbles trapped between the seed layers (1b) on the surfaces of the resin insulating layers (1a) and the liquid resists 2 when the liquid resists 2 are applied onto the seed layers (1b) with the coating rolls (3a) as described above are thought to dissolve in the resist layers (1d), and thereby, air bubbles trapped between the seed layers (1b) on the surfaces of the resin insulating layers (1a) and the liquid resists 2 when the liquid resists 2 are applied onto the seed layers (1b) having a low surface roughness in the printed wiring board 1 can be effectively prevented from forming voids later.

The above description is based on the illustrated embodiments. However, a method for manufacturing a printed wiring board and a laminating system of the present invention are not limited to the above-described embodiments, and may be appropriately modified within the scope of the claims. For example, the liquid resist coating device (D1) may be formed of a spray coater, a screen printing device, a spin coater, a curtain coater, or the like, instead of the roll coater 3, and as the liquid resist drying device (D2), a hot plate or the like may be used instead of the heat drying device 4 that is similar to an oven. Further, the present invention may also be applied to coating of a coreless multilayer printed wiring board, a single-layer printed wiring board, or a single-sided printed wiring board with a liquid resist.

The coating device of Japanese Patent Application Laid-Open Publication No. H05-068922 includes a roll coater of FIG. 1 in which a liquid resist is applied to both sides of a substrate by roll surfaces positioned above and below the substrate, and a final drying device (not illustrated) provided at a rear part of the roll coater.

In forming a conductor circuit using a semi-additive method, the semi-additive method may include applying a liquid resist on a seed layer, drying the liquid resist to form a resist layer, forming a plating resist from the resist layer by exposure and development, and forming an electrolytic plating film on the seed layer exposed from the plating resist.

It is difficult to manufacture conductor circuits with a yield of 100% using a semi-additive method including such processes. One of causes of defects is short circuiting. And, one of causes of a short circuit is thought to be a void between a seed layer and a coating film of a liquid resist on the seed layer.

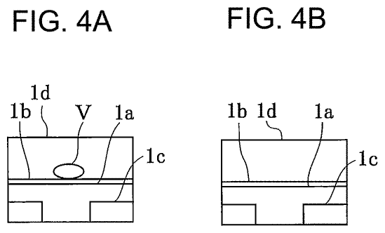

FIG. 4(A) illustrates an example of a void (V) between a seed layer (1b) formed on a surface of a resin insulating layer (1a) covering a lower-layer conductor layer (1c) and a resist layer (1d) formed by applying a liquid resist on the seed layer (1b). In the example of FIG. 4(A), when an electrolytic plating film is formed on the seed layer (1b) exposed from a plating resist formed from the resist layer (1d), the electrolytic plating film is also deposited in the void (V) between the seed layer (1b) and the resist layer (1d). Therefore, conductor circuits adjacent to each other in the conductor layer (1c) are connected by the electrolytic plating film in the void (V). On the other hand, in the example of FIG. 4(B), there is no void (V) between the seed layer (1b) and the resist layer (1d).

A method for manufacturing a printed wiring board according to an embodiment of the present invention includes: preparing a resin insulating layer; forming a seed layer on a surface of the resin insulating layer; applying liquid resist on the seed layer; forming a resist layer by drying the liquid resist applied on the seed layer; applying heat and pressure to the resist layer formed on the seed layer; forming a plating resist from the resist layer using a photographic technology; forming an electrolytic plating film on the seed layer exposed from the plating resist; removing the plating resist; and removing the seed layer exposed from the electrolytic plating film, wherein the applying of pressure and heat to the resist layer formed on the seed layer is simultaneously conducted with respect to an entire surface of the resist layer.

Further, a coating system according to an embodiment of the present invention includes: a liquid resist coating device that applies a liquid resist on a seed layer formed on a resin insulating layer; a liquid resist drying device that forms a resist layer by drying the liquid resist applied on the seed layer formed on the resin insulating layer; and a heat and pressure application device that applies heat and pressure to an entire surface of the resist layer.

Obviously, numerous modifications and variations of the present invention are possible in light of the above teachings. It is therefore to be understood that within the scope of the appended claims, the invention may be practiced otherwise than as specifically described herein.

What is claimed is:

1. A method for manufacturing a printed wiring board, comprising:
forming a seed layer on a surface of a resin insulating layer;
applying liquid resist on the seed layer formed on the surface of the resin insulating layer;
drying the liquid resist applied on the seed layer such that a resist layer is formed on the seed layer;
applying pressure and heat simultaneously to an entire surface of the resist layer formed on the seed layer;
forming a plating resist on the seed layer from the resist layer formed on the seed layer using a photographic technology;
forming an electrolytic plating film on part of the seed layer exposed from the plating resist;
removing the plating resist from the seed layer; and
removing part of the seed layer exposed from the electrolytic plating film.

2. The method of claim 1, wherein the applying of pressure and heat to the resist layer is conducted after the forming of the resist layer on the seed layer.

3. The method of claim 1, wherein the applying of pressure and heat to the resist layer is conducted before the forming of the plating resist.

4. The method of claim 1, wherein the pressure is applied to the resist layer via a pressure application gas.

5. The method of claim 4, wherein the heat is applied to the resist layer via the pressure application gas.

6. The method of claim 1, wherein the forming of the resist layer includes preparing an intermediate substrate, and the applying of the pressure includes positioning the intermediate substrate in a pressure application container and introducing a pressure application gas in the pressure application container.

7. The method of claim 6, wherein the heat is applied to the resist layer via the pressure application gas.

8. The method of claim 4, wherein the pressure application gas is compressed air.

9. The method of claim 1, wherein the pressure is applied to the resist layer via a pressing plate.

10. The method of claim 9, wherein the heat is applied to the resist layer via the pressing plate.

11. The method of claim 1, further comprising:
roughening the surface of the resin insulating layer before the forming of the seed layer.

12. The method of claim 11, wherein the roughening includes roughening the surface of the resin insulating layer such that an arithmetic mean roughness Ra of a surface of the seed layer formed on the resin insulating layer becomes 0.3 μm or less.

13. A coating system, comprising:
a liquid resist coating device configured to apply a liquid resist on a seed layer formed on a resin insulating layer;
a liquid resist drying device configured to dry the liquid resist applied on the seed layer formed on the resin insulating layer and form a resist layer on the seed layer; and
a pressure and heat application device configured to apply pressure and heat to an entire surface of the resist layer.

14. The coating system according to claim 13, wherein the liquid resist coating device comprises a roll coater including a doctor bar configured to supply the liquid resist at a predetermined thickness, and a coating roll configured to apply the liquid resist supplied from the doctor bar onto the seed layer at a predetermined thickness.

15. The coating system according to claim 13, wherein the pressure and heat application device includes a pressure application container configured to accommodate the resin insulating layer on which the resist layer is formed on the seed layer, a heat source positioned in the pressure application container, and a pressure source positioned in the pressure application container.

16. The coating system according to claim 15, wherein the heat source includes an upper hot plate positioned above the resin insulating layer on which the resist layer is formed on the seed layer, and a lower hot plate positioned below the resin insulating layer on which the resist layer is formed on the seed layer.

17. The coating system according to claim 15, wherein the pressure source is a pressure application gas.

18. The coating system according to claim 16, wherein the pressure and heat application device includes a spacer inserted between a peripheral edge part of the upper hot plate and a peripheral edge part of the lower hot plate.

19. The coating system according to claim 17, wherein the pressure application gas is compressed air.

20. The coating system according to claim 13, wherein the pressure and heat application device includes a plurality of pressing plates configured to sandwich the resin insulating layer on which the resist layer is formed on the seed layer and to apply the heat and the pressure to the resist layer.
